(19) United States
(12) Patent Application Publication
(10) Pub. No.: US 2010/0063761 A1
(43) Pub. Date: Mar. 11, 2010

(54) Clock Jitter Analysis

(76) Inventor: Gerald L. Frenkil, Concord, MA (US)

Correspondence Address: Haynes and Boone, LLP;IP Section, 2323 Victory Avenue, SUITE 700, Dallas, TX, 75219, US

(21) Appl. No.: 12/234,395

(22) Filed: Sep. 19, 2008

Related U.S. Application Data
(60) Provisional application No. 61/096,226, filed on Sep. 11, 2008.

(51) Int. Cl. G01R 13/00

(52) U.S. Cl. 702/69

(57) ABSTRACT

A tool and a method analyze variations in signal timing, especially timing in a clock signal, commonly known as “clock Jitter.” The tool and method provide advantages over conventional analysis approaches, such as comprehensive coverage of all clocks in a design, taking into account all signal coupling effects, ease of use, ability to automatically identify individual jitter sources, and efficient use of computing resources.

### CROSS REFERENCE TO RELATED APPLICATIONS

The present application relates to and claims priority of U.S. provisional patent application (“Provisional Application”), Ser. No. 61/096,226, entitled “Clock Jitter Analysis,” filed on Sep. 11, 2008. The Provisional Application is hereby incorporated by reference in its entirety.

### BACKGROUND OF THE INVENTION

1. Field of the Invention

The present invention relates to electronic design automation (EDA) tools and methods for integrated circuits. In particular, the present invention relates to EDA tools for timing analysis of electronic circuits.

2. Discussion of the Related Art

A significant concern in the design of high-speed integrated circuits is the analysis and control of clock jitter. Jitter refers to the variations of a signal's transition times relative to the transitions' ideal positions in time¹. The variations in signal timing arise from the variations in operating conditions, such as signal coupling and voltage drop. FIG. 1 shows typical variations in a clock signal. In the example of FIG. 1, the beginning points and the mid points of the durations labeled “Cycle 1,” “Cycle 2,” . . . “Cycle n” represent the ideal positions in time for the leading and the trailing edges of the clock signal. Due to the instantaneous operating conditions, the actual positions in time of both the leading (i.e., rising) edge and the trailing (i.e., falling) edge of the signal vary relative to their ideal positions. FIG. 2 shows the result of overlaying the variations in a number of cycles, relative to their ideal positions. To ensure reliable operation across a variety of operating conditions and applications, these timing variations in the clock signals must be taken into account, since the clock signals establish the timing references for all other signals in an integrated circuit. Variations in a timing reference may lead to timing violations in data signals that rely on the timing reference. For example, if jitter in a clock signal causes the clock signal to arrive “early” relative to its ideal arrival time, a data setup violation may occur (i.e., the data may not have arrived sufficiently in advance of the clock signal for proper circuit operation (e.g., being properly latched into a register)). Similarly, if jitter on the clock signal causes the clock signal to arrive “late,” relative to its ideal arrival time, a data hold violation may occur (i.e., the data may not be held for a sufficient length of time after the clock signal arrived for proper circuit operation). Thus, for high-speed circuit operations, jitter characteristics of clock signals must be taken into consideration at the time the circuit is designed. ¹ See, for example, Digital Timing Measurements by W. Maichen, Springer, 2006.

FIG. 3 provides an example of how jitter may lead to a timing violation. As shown in FIG. 3, within duration time interval 301, if the actual transitions of the clock signal and data signal are too close to each other, a setup time violation may occur. Similarly, within duration 302, if the actual transitions of the clock signal and the data signal are too close to each other, a hold time violation may occur.

In a conventional design method, jitter is analyzed during the design phase of an integrated circuit using circuit simulation (e.g., circuit simulation using SPICE or similar transistor or gate level simulation software). Before running a circuit simulation, an integrated circuit designer must model the circuit in a reduced form to allow handling in a circuit simulator (due to circuit simulator's generally significant capacity limitations), and must design a proper set of input stimuli for the circuit, not merely only for the signals to be analyzed, but also for any other signals that would directly or indirectly affect the signals to be analyzed. A circuit simulation is often run on several machines in parallel in order to reduce the total elapsed time. The integrated circuit designer then inspects the results to determine both the magnitude and the source of the jitter. A tool that is used to assist in the analysis is the “eye diagram,” which is obtained by overlaying individual waveforms of a signal obtained from a number of simulations, as shown in FIG. 4. Typically, the eye diagram represents waveforms from different simulations by different colors, so as to allow the integrated circuit designer to visually inspect the variations in signal timing.

In the prior art, circuit simulation is favored for jitter analysis primarily because of familiarity—i.e., most designers are familiar with simulation and simulation-based approaches for jitter analysis. However, circuit simulation has the following disadvantages: (a) the jitter analysis is not a worst case analysis (i.e., the results obtained by simulation understate the actual jitter conditions because only a limited set of operating conditions affecting jitter can be simulated within a reasonable investment of simulation time); (b) it is difficult to correctly design a complete and practical set of input signal stimuli to simulate jitter-affecting events (i.e., the number of input stimuli, the exact timings and switching directions of those stimuli, and the practical operational conditions make exhaustive simulations impossible); (c) only a small portion of a circuit of interest can be simulated at one time, because of capacity limitations of the simulators; and (d) simulators are largely designed for timing simulation and provide little or no support for determining the sources or causes of jitter.

### SUMMARY

According to one embodiment of the present invention, a tool and a method analyze variations in signal timing, especially variations in the timing of transitions in a clock signal, commonly known as “clock Jitter.” The tool and method provide advantages over conventional analysis approaches, such as comprehensive coverage of all clocks in a design, taking into account all signal coupling effects, ease of use, ability to automatically identify individual jitter sources, and efficient use of computing resources.

The present invention is better understood upon consideration of the detailed description below in conjunction with the accompanying drawings.

### BRIEF DESCRIPTION OF THE DRAWINGS

FIG. 1 shows typical variations in a clock signal.

FIG. 2 shows the result of overlaying the variations of a number of cycles, relative to their ideal positions.

FIG. 3 provides an example of how jitter may lead to a timing violation.

FIG. 4 shows an “eye diagram” obtained by overlaying individual waveforms of a signal obtained from a number of simulations.

FIG. 5 shows the values of a jitter component of each output signal of a logical instance, so as to allow the designer to trace the source of jitter in the logic circuit.

FIG. 6 contrasts the jitter analysis results achieved under a circuit simulation method with a method of the present invention.

FIG. 7 is a flow chart of a jitter-analysis method, in accordance with one embodiment of the present invention.

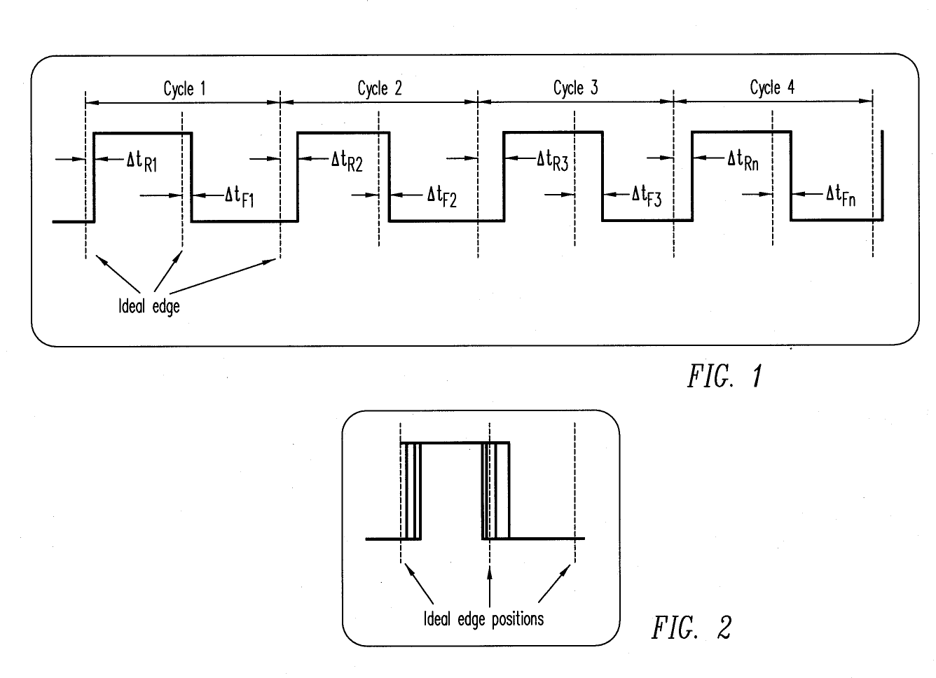

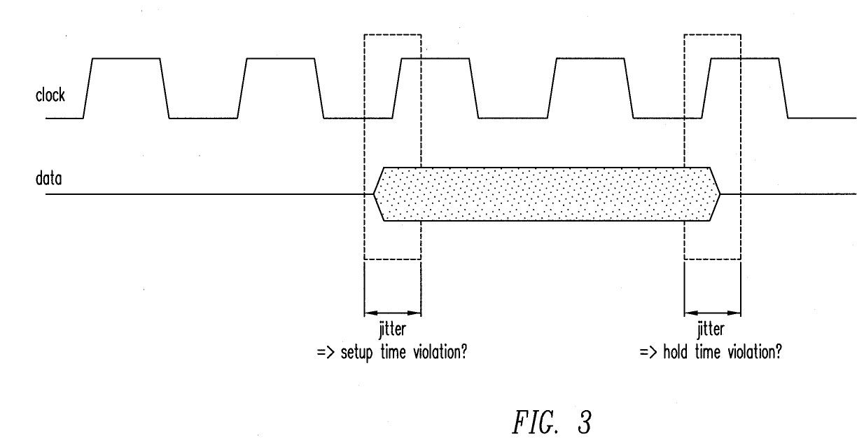

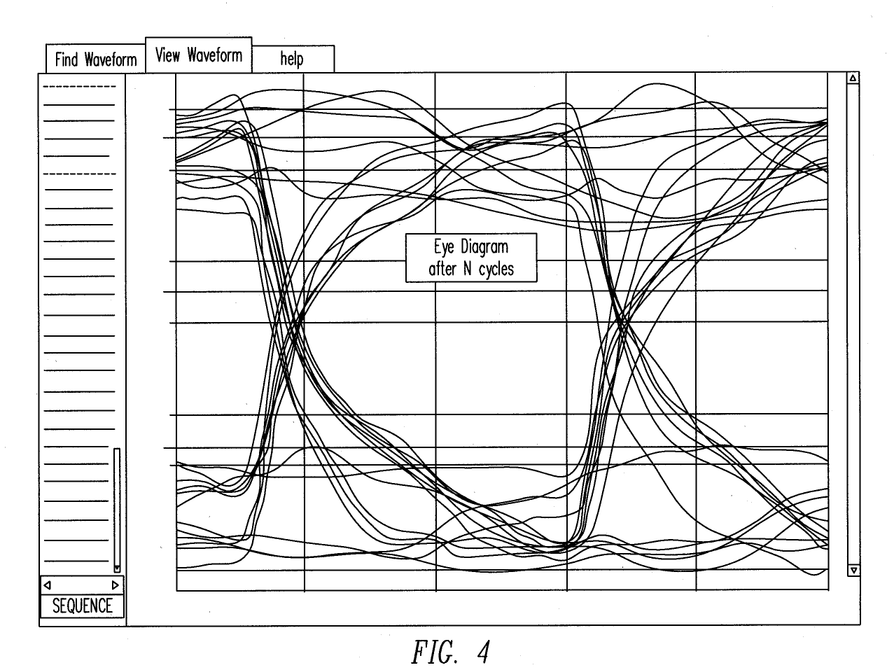

### DETAILED DESCRIPTION OF THE PREFERRED EMBODIMENTS

The present invention provides an efficient and robust method for analyzing jitter in clock signals using static timing analysis (STA), which is a faster and more comprehensive approach as compared to circuit simulation. Unlike circuit simulation, STA has the advantage that it analyzes all timing and signal integrity coupling events, in addition to those specified by the input stimuli. Further, STA can analyze the entire design at once, not just a reduced circuit created to meet the simulator's capacity constraints.

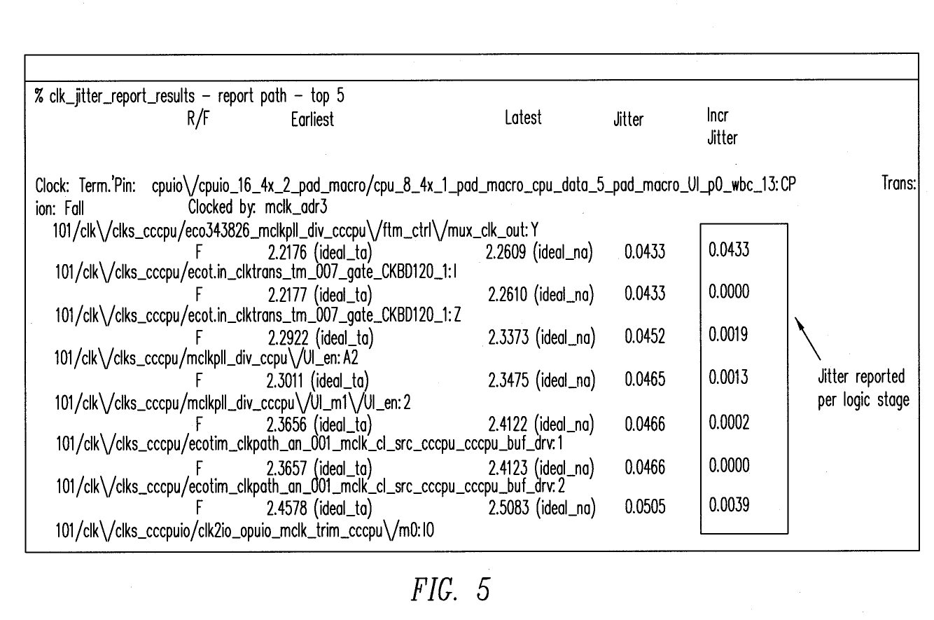

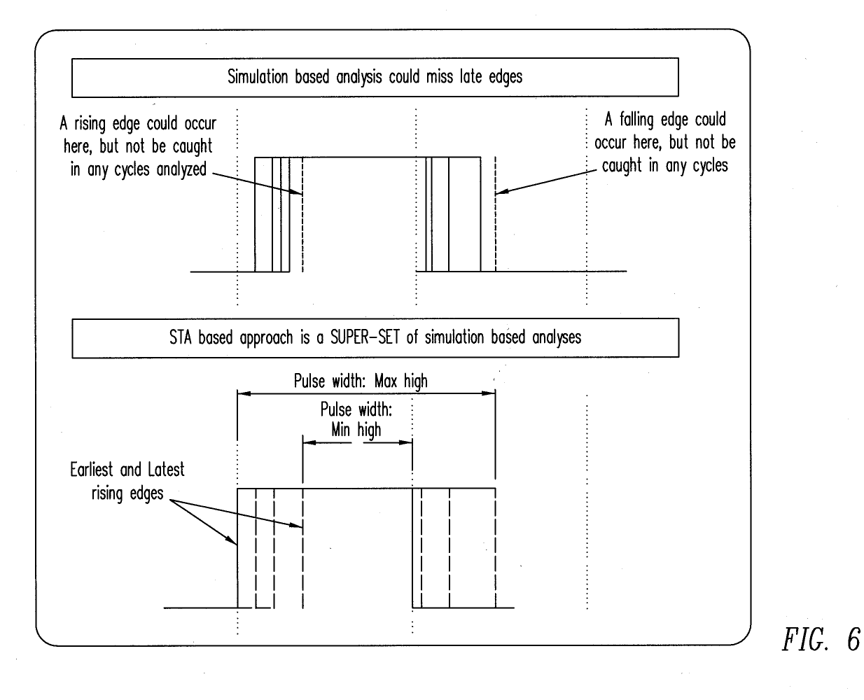

A method according to the present invention uses one or more runs of an STA to compute circuit timings, so that 100% coverage of all possible timing paths is achieved, which is not achievable using circuit simulation. Multiple runs allow the designer to compute the earliest and latest signal arrival times, as affected under different values of design parameters. The number of runs necessary to achieve a high level of confidence is in the order of a few runs, whereas a circuit simulation-based approach may not be able to achieve the same confidence level, regardless of the number of simulation runs. The method of the present invention also uses voltage-aware delay calculation in the STA to compute a voltage component of jitter (i.e., the results of a voltage drop analysis provide adjustments to the calculated delays for each logical instance). A signal integrity (SI) analysis may be used to compute an SI component of jitter; SI analysis provides 100% coverage of all possible signal integrity coupling events, which is not achievable under a circuit simulation approach. The method also enables easy isolation and identification of jitter sources, as shown in FIG. 5. In FIG. 5, the jitter component of each output signal of a logical instance is calculated, so as to allow the designer to trace the source of jitter in the logic circuit.

The term “jitter” refers to a variety of jitter types and measurements, such as cycle-to-cycle jitter, period jitter, pulse width distortion, and duty-cycle distortion.

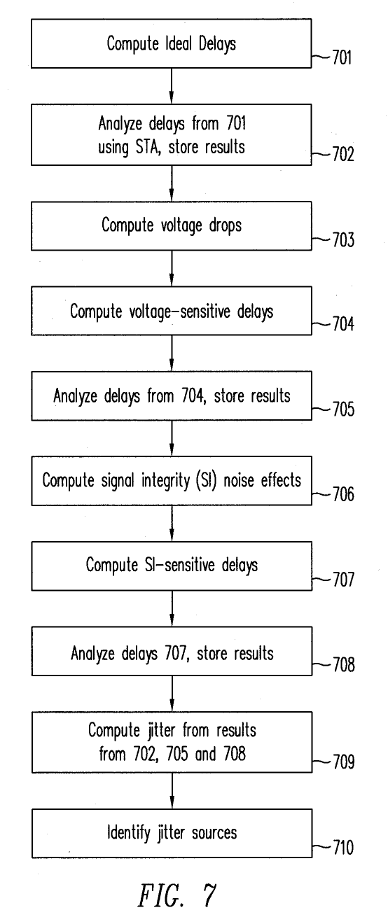

FIG. 7 is a flow chart of a jitter-analysis method, in accordance with one embodiment of the present invention. According to FIG. 7, at step 701, an STA analysis is performed to calculate ideal delays. Ideal delays are the propagation delays through each logic element of the design, assuming ideal conditions. The ideal conditions assumes no voltage drop occurring on either the power or the ground distribution networks (“ideal supply voltage conditions”) and that there are no capacitive cross-coupling effects between neighboring signals affecting the delays (i.e., “ideal timing conditions”).

At step 702, the delays calculated for each individual element in step 701 are used to analyze delays along logical paths from a starting point. In the case of a clock signal, delays are calculated from a root node of a clock signal to each of its leaves or end points. Each end point can potentially have multiple arrival times, depending upon the number of different logical conditions that could cause a transition at that end point. The earliest and the latest arrival times (for both rising and falling transitions) are stored for each node along a logical path. In one implementation, for each node along each logic path, the following information (labeled “a”) is stored:
(a) t_rise_earliest_cond_a (i.e., the earliest possible rising transition under condition a);
(b) t_rise_latest_cond_a (i.e., the latest possible rising transition under condition a);
(c) t_fall_earliest_cond_a (i.e., the earliest possible falling transition under condition a);
(d) t_fall_latest_cond_a (i.e., the latest possible falling transition under condition a).

At step 703, voltage drops are computed on the power and ground supply conductors connected to the logical element of the circuit, so as to allow subsequent determination of the effects upon the delays due to a non-ideal supply voltage conditions.

At step 704, the power and ground voltages computed at step 703 are used to calculate the delays (“voltage-sensitive delays”) through each circuit element. The delays calculated at this step are non-ideal, since ideal supply voltage conditions are not assumed.

At step 705, the voltage-sensitive delays calculated for each individual element at step 704 are used to analyze delays along logical paths, in substantially the same manner as described above at step 702. From this analysis (labeled “b”), the earliest and latest arrival times are stored for each node.
(e) t_rise_earliest_cond_b (i.e., the earliest possible rising transition under condition b);
(f) t_rise_latest_cond_b (i.e., the latest possible rising transition under condition b);
(g) t_fall_earliest_cond_b (i.e., the earliest possible falling transition under condition b);
(h) t_fall_latest_cond_b (i.e., the latest possible falling transition under condition b).

At step 706, each possible switching event is computed and analyzed to determine whether or not the event affects the timing of another event. This analysis identifies the possibility of any two signals that are connected through a parasitic coupling capacitance transitioning at the same instant in time. When two signals can potentially switch in the same direction at the same time, a faster transition time is assigned to each signal. Conversely, when two signals can potentially switch in the opposite direction at the same time, a slower transition time is assigned to each signal.

At step 707, the event “pairings” (i.e., coupled signal pairs transitioning at the same time) determined at step 706 are used to calculate delays (“SI-sensitive delays”) through each circuit element. Delay calculations are performed in substantially the same manner as delay calculations of step 701 above, except that the event pairings are used to adjust the ideal delays. In practice, steps 706 and 707 may be carried out in a single step.

At step 708, the SI-sensitive delays of step 707 are used to analyze delays along logical paths in substantially the same manner as the delay analyses of steps 702 and 705 described above, except the calculated delays of step 708 reflect the SI (signal integrity) effects determined in step 706 above. From this analysis (labeled “c”), the earliest and latest arrival times are stored for each node.
(i) t_rise_earliest_cond_c (i.e., the earliest possible rising transition under condition c);
(j) t_rise_latest_cond_c (i.e., the latest possible rising transition under condition c);
(k) t_fall_earliest_cond_c (i.e., the earliest possible falling transition under condition c);
(l) t_fall_latest_cond_c (i.e., the latest possible falling transition under condition c).

At step 709, using the results (a) to (l) stored from analyses carried out at steps 702, 705 and 708, the earliest and latest possible rising and falling events of each node are calculated:

t_rise_earliest=MIN(t_rise_earliest_cond_{—}a,t_rise_earliest_cond_{—}b,t_rise_earliest_cond_{—}c)

t_rise_latest=MAX(t_rise_latest_cond_{—}a,t_rise_latest_cond_{—}b,t_rise_latest_cond_{—}c)

t_fall_earliest=MIN(t_fall_earliest_cond_{—}a,t_fall_earliest_cond_{—}b,t_fall_earliest_cond_{—}c)

t_fall_latest=MAX(t_fall_latest_cond_{—}a,t_fall_latest_cond_{—}b,t_fall_latest_cond_{—}c)

From these events, jitter may be characterized by the timings of rising events and falling events, respectively, as:

t_rise_jitter=t_rise_latest−t_rise_earliest

t_fall_jitter=t_fall_latest−t_fall_earliest

At step 710, based on the calculations in step 709, jitter is known for all nodes along any path of interest. Further, accumulation of jitter along a path from a source node to a destination node can be determined, thereby enabling identifying the nodes along the path at which the jitter is introduced as jitter sources. Additionally, the components of each jitter source (which scenario resulted in the earliest and latest arrival times) are identified as well, as illustrated by FIG. 5 above.

While the method of FIG. 7 uses ideal delays, voltage-sensitive delays and SI-sensitive delays for jitter analysis, the methods of the present invention are not so limited. In fact, the methods of the present invention are applicable to any operating condition that affects timing (e.g., making signal timings deviate from the ideal delay conditions). For example, rather than ideal delays, delays under a different voltage drop condition may be used. As another example, process-sensitive delays can be calculated based on timing models of manufacturing process variations. The methods of the present invention require consideration of fewer conditions than any other method known in the prior art because the SI component is deterministically and reliably bounded for both best-case and worst-case conditions, which is not achievable in the methods of the prior art.

FIG. 6 contrasts the jitter analysis results achieved under a circuit simulation method with a method of the present invention. As shown in FIG. 6, because the earliest arrival times for the rising edge and the falling edge of each signal at any node is computed, a jitter analysis under the present invention provides timing bounds for the jitter affecting that signal at that node. However, in a circuit simulation-based jitter analysis, the timings of rising and falling edges under conditions not simulated are missed.

The above detailed description is provided to illustrate specific embodiments of the present invention and is not intended to be limiting. Various modifications and variations within the scope of the present invention are possible. The present invention is set forth in the following claims.

I claim:

1. A method for analyzing clock signal jitter in an electronic circuit, comprising:
applying a static timing analysis on the electronic circuit to calculate for each signal at each electronic node an earliest arrival time and a latest arrival time for both a rising signal transition and a falling signal transition; and
calculating for each signal a rising edge jitter as a difference between the earliest arrival time and latest arrival time for the rising signal transition and a falling edge jitter as a difference between the earliest arrival time and the latest arrival time for the falling signal transition.

2. A method as in claim 1, wherein the static timing analysis is applied under one or more operating conditions, the static timing analysis providing for each signal an earliest arrival time and a latest arrival time for each signal transition under each operating condition.

3. A method as in claim 2, the operating conditions being selected from the group consisting of ideal delay conditions, non-ideal timing condition, non-ideal supply voltage condition and process variations.

4. A method as in claim 3, wherein the non-ideal supply voltage condition is used to calculate voltage-sensitive delays.

5. A method as in claim 3, wherein the non-ideal timing condition includes worst case signal integrity effects.

6. A method as in claim 2 wherein, for each signal, the earliest arrival time used in calculating jitter for each signal transition is the minimum earliest arrival time among the earliest arrival times calculated for that signal for that signal transition under the operating conditions.

7. A method as in claim 2 wherein, for each signal, the latest arrival time used in calculating jitter for each signal transition is the maximum latest arrival time among the latest arrival times calculated for that signal for that signal transition under the operating condition;

8. A method as in claim 1, wherein applying a static timing analysis applies to the entire electronic design.

9. A method as in claim 1, further comprising locating the source of jitter using the rising edge jitter and the trailing edge jitter.

10. A method as in claim 1, wherein applying the static timing analysis comprises calculating propagation delays in logical paths.

11. A computer-readable medium encoded thereon computer-executable instructions for analyzing clock signal jitter in an electronic circuit, wherein said instructions, when executed, perform:
applying a static timing analyzer on the electronic circuit to calculate for each signal at each electronic node an earliest arrival time and a latest arrival time for both a rising signal transition and a falling signal transition; and
calculating for each signal a rising edge jitter as a difference between the earliest arrival time and latest arrival time for the rising signal transition and a falling edge jitter as a difference between the earliest arrival time and the latest arrival time for the falling signal transition.

12. A computer-readable medium as in claim 11, wherein the static timing analysis is applied under one or more operating conditions, the static timing analysis providing for each signal an earliest arrival time and a latest arrival time for each signal transition under each operating condition.

13. A computer-readable medium as in claim 12, the operating conditions being selected from the group consisting of ideal delay conditions, non-ideal timing condition, non-ideal supply voltage condition, and process variations.

14. A computer-readable medium as in claim 13, wherein the non-ideal supply voltage condition is used to calculate voltage-sensitive delays.

15. A computer-readable medium as in claim 13, wherein the non-ideal timing condition includes worst case signal integrity effects.

16. A computer-readable medium as in claim 12 wherein, for each signal, the earliest arrival time used in calculating jitter for each signal transition is the minimum earliest arrival time among the earliest arrival times calculated for that signal and that signal transition under the operating conditions.

17. A computer-readable medium as in claim 12 wherein, for each signal, the latest arrival time used in calculating jitter for each signal transition is the maximum latest arrival time among the latest arrival times calculated for that signal and that signal transition under the operating condition;

18. A computer-readable medium as in claim 11, wherein applying a static timing analysis applies to the entire electronic design.

19. A computer-readable medium as in claim 11, wherein further comprising instructions for locating the source of jitter using the rising edge jitter and the trailing edge jitter.

20. A computer-readable as in claim 11, wherein applying the static timing analysis comprises calculating propagation delays in logical paths.
